(19) United States
(12) Patent Application Publication
(10) Pub. No.: US 2008/0156772 A1
(43) Pub. Date: Jul. 3, 2008

(54) METHOD AND APPARATUS FOR WAFER EDGE PROCESSING

(76) Inventors: Yunsang Kim, Monte Sereno, CA (US); Jack Chen, Fremont, CA (US); Grace Fang, Fremont, CA (US); Andrew Bailey, Pleasanton, CA (US)

Correspondence Address: IPSG, P.C., P.O. BOX 700640, SAN JOSE, CA, 95170, US

(21) Appl. No.: 11/618,572

(22) Filed: Dec. 29, 2006

(51) Int. Cl. H01L 21/306; C23F 1/02

(52) U.S. Cl. 216/71; 156/345.48

(57) ABSTRACT

Methods and apparatus for remedying arc-related damage to the substrate during plasma bevel etching. A plasma shield is disposed above the substrate to prevent plasma, which is generated in between two annular grounded plates, from reaching the exposed metallization on the substrate. Additionally or alternatively, a carbon-free fluorinated process source gas may be employed and/or the RF bias power may be ramped up gradually during plasma generation to alleviate arc-related damage during bevel etching. Also additionally or alternatively, helium and/or hydrogen may be added to the process source gas to alleviate arc-related damage during bevel etching.

### BACKGROUND OF THE INVENTION

Plasma processing has long been employed to process substrates and to create devices on the substrate. Generally speaking, the substrate may be processed in a plasma processing chamber through multiple steps that are designed to ultimately deposit and etch selected areas of the substrate to create the electronic devices thereon. In any given substrate, the central portion of the substrate is typically divided into a plurality of dies, each of which represents an electronic device such as an integrated circuit that the manufacturer wishes to form on the substrate. The areas at the periphery of the substrate generally are not processed into electronic devices and form a wafer edge.

The various processing steps in a plasma processing chamber may create unwanted residues or deposits which need to be cleaned before the next processing step can be initiated. For example, following a metallization deposition step, the periphery area of the wafer may contain unwanted sputtered metal particles that need to be cleaned before the next processing step. As another example, the etching step may create polymer deposition throughout the chamber, including on the periphery region of the substrate. This polymer deposition, as well as any other unwanted residues, needs to be cleaned before the next processing step to ensure that these residues do not contaminate subsequent processing steps. As used herein, the periphery region surrounding this substrate that is outside of the device area is referred by the term “wafer edge.” Thus, the wafer edge represents the concentric, ring-like area surrounding the wafer that is outside of the device area.

To facilitate discussion, FIG. 1 shows an example wafer 102 which may represent, for example, a 300 mm wafer. For ease of illustration, only a portion of example wafer 102 is shown. When viewed from the top, there exists a device area 108 extending to the left of reference number 104 where devices are formed on the wafer using the various plasma processing steps. As discussed, the device area 108 tends to exist in the center portion of the wafer. To the right of reference number 104 extending from the top of the substrate to the bottom side of the substrate to the right of reference number 10, there exists a region referred to herein as wafer edge 106. The wafer edge area 106, representing the area at the periphery of wafer 102 on which devices are not formed. Nevertheless, unwanted deposition may adhere to wafer edge area 106 during plasma processing steps and cleaning needs to be performed to ensure that any unwanted deposition on wafer edge area 106 does not contaminate subsequent plasma process steps.

In the prior art, there are provided plasma processing systems configured for cleaning the wafer edge area 106. In these plasma processing systems, wafer edge plasma is formed in the region of the wafer edge area to perform cleaning of the wafer edge area. Other areas such as the device area 108 to the left of reference number 104 of wafer 102 are generally left undisturbed during wafer edge cleaning.

However, during certain plasma wafer edge cleaning procedures, devices on the substrate have been observed to suffer an inordinate degree of damage. Further investigation reveals that if there exist exposed metal features such as metal lines or artifacts of a metal layer (such as a copper layer, a titanium layer, a titanium nitrite layer, for example), the exposed metal lines or artifacts of a metal layer act as RF antennas during the plasma wafer edge cleaning procedure and attract arcs from the plasma sheath to the substrate. The exposed metal lines then act as conductive lines to conduct the high current arcs from the plasma to the devices in the device area 108, causing electrical damage to the device and leading to reduced yield.

While not wishing to be bound by theory since a thorough understanding of the mechanism of arcing in plasma processing systems is not fully understood, it is believed that a contributing factor may be the potential difference between the plasma sheath, which tends to be positively biased, and the substrate, which tends to be negatively biased. The favorable condition for arcing may be further enhanced by the presence of exposed metal layers, which may be a single metal layer or multiple metal layers, or metal conductors or may be a phenomenon that is created by the presence of unwanted sputtered metal deposition which causes arcing. Arcing during plasma processing is a problem not only because it causes the aforementioned electrical damage to the devices but also because arcing represents an uncontrolled event. Uncontrolled events are generally undesirable during plasma processing because the parameters are uncontrolled and the unintended results are often damaging.

### SUMMARY OF INVENTION

The invention relates, in an embodiment, to a plasma processing system having a plasma processing chamber configured for processing a substrate. The plasma processing system includes a RF power source. The plasma processing system also includes a lower electrode configured to support the substrate during the processing. The lower electrode receives at least an RF signal from the RF power source for generating a plasma within the plasma processing chamber during the processing. The plasma processing system further includes a first annular grounded electrode disposed above the substrate. The plasma processing system yet also includes a second annular grounded electrode disposed below the substrate. The first annular grounded electrode and the second annular grounded electrode is disposed such that a circumferential edge of the substrate is exposed in a direct line-of-sight manner to at least a portion of the first annular grounded electrode and at least a portion of the second annular grounded electrode. The plasma processing system yet further includes a plasma shield disposed above at least a portion of the substrate. The plasma shield is configured to prevent the plasma from being formed in a region between the plasma shield and the portion of the substrate during the processing.

The above summary relates to only one of the many embodiments of the invention disclosed herein and is not intended to limit the scope of the invention, which is set forth in the claims herein. These and other features of the present invention will be described in more detail below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 shows an example wafer which may represent, for example, a 300 mm wafer.

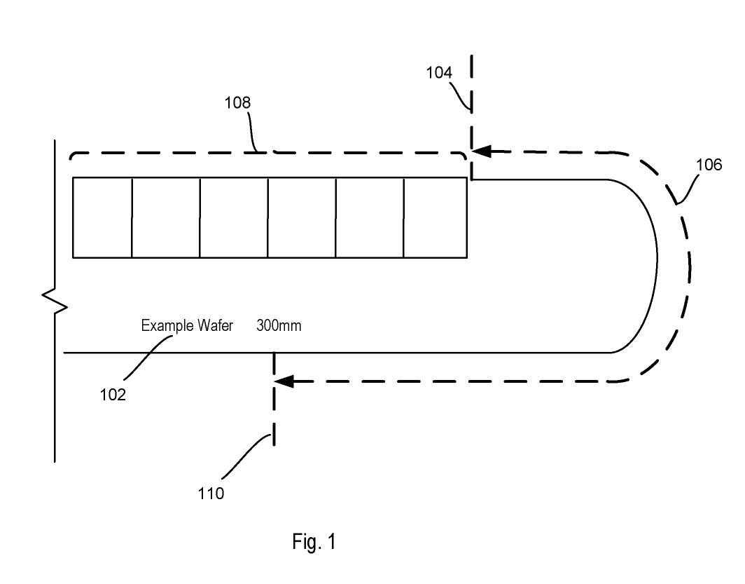

FIG. 2 shows, in accordance with an embodiment of the present invention, a simplified diagram of the relevant portion of a plasma wafer edge cleaning system.

FIG. 3 shows, in accordance with an embodiment of the invention, various techniques that may be employed to substantially reduce or eliminate arcing events during a plasma wafer edge cleaning process in a plasma wafer edge cleaning system.

### DETAILED DESCRIPTION OF EMBODIMENTS

The present invention will now be described in detail with reference to a few embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

In accordance with embodiments of the invention, the aforementioned arcing problem may be addressed by providing the process engineer with one or more tools to alleviate arcing. In an embodiment, a plasma shield is provided above the wafer and is extended beyond the wafer edge in order to inhibit plasma from being formed in the area above the substrate where exposed metal particles or layers may exist. By providing a plasma shield over the top horizontal surface of the substrate and extending the plasma shield beyond the wafer edge, embodiments of the invention ensure that plasma etching only occurs on the exposed edge area of the wafer that does not contain the exposed metal layer and/or metal particles. In this manner, arcing from the plasma sheath to the wafer is substantially eliminated, consequently substantially eliminating arc-related damage to the devices on the substrate.

In another embodiment, the aforementioned arcing problem may be alleviated, alternatively or additionally, by using an etching source gas that does not include carbon. The use of a non-carbon etching source gas to form a plasma for the plasma wafer edge cleaning process has been found to substantially reduce or eliminate the formation of arcs from the plasma sheath to the substrate.

In another embodiment, helium and/or hydrogen may be added to the plasma etching source gas in order to substantially reduce or eliminate arcing from the plasma sheath to the substrate. The addition of the helium and/or hydrogen may be performed alternatively or additionally.

In another embodiment, RF power may be provided gradually to the plasma to strike and sustain the plasma in the wafer edge area. This is in contrast to prior art techniques that provide RF power as a step function. In accordance with an embodiment of the invention, power is ramped up gradually in order to eliminate the spike in the reflected power which is believed to substantially reduce or eliminate the formation of arcs from the plasma sheath to the substrate. The gradual ramping of the RF power may be performed by software that is integrated with the automated process control computer employed to control the wafer edge cleaning plasma processing chamber. The software controlled gradual ramp up of the RF power may be performed alternatively or additionally to the previous approaches (e.g., extending the plasma shield past the wafer edge, using non-carbon etching source gas, and/or adding helium/hydrogen).

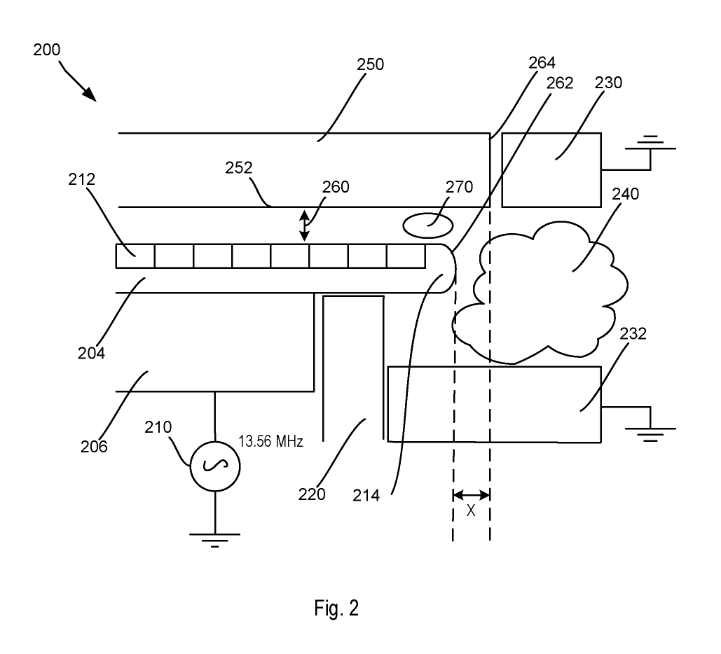

FIG. 2 show, in accordance with an embodiment of the present invention, a simplified diagram of the relevant portion of a plasma wafer edge cleaning system. In a wafer edge cleaning system 200, a substrate 204 is disposed above a chuck 206 during plasma wafer edge cleaning. The chuck 206 is coupled to an RF biased power supply 210 which may provide one or more RF signals, wherein the RF signals may be a single frequency or multiple-frequency signals, to chuck 206 to strike and sustain a plasma for the plasma wafer edge cleaning. Substrate 204 includes a device area 212 which tends to be disposed towards the center portion of substrate 204. At the periphery of substrate 204 is a concentric wafer edge area 214 on which devices are not formed.

As mentioned earlier, during the various plasma processing steps that are employed to form devices in device area 212, unwanted depositions of materials such as polymers or metal residues may adhere to the surface of wafer edge area 214 and may need to be cleaned to ensure that the unwanted depositions do not contaminate subsequent plasma processing steps. A conventional dielectric bottom ring 220 formed of a suitable dielectric material surrounds chuck 206. Up to now, the arrangement discussed has been conventional and would be well-known to those familiar with capacitively-coupled plasma processing systems.

To perform plasma wafer edge cleaning, grounded plates are provided in the regions where plasma is expected to be formed. In the example of FIG. 2, annular grounded plate 230 and annular grounded plate 232 which may be formed of a suitable conductor such as aluminum, are disposed above and below a plasma region 240. As can be seen in FIG. 2, these annular grounded plates 230 and 232 are disposed such that there is a direct line-of-sight exposure of circumferential edge 262 of the substrate to at least portions of the annular grounded plates 230 and 232.

These annular grounded plates act as grounded electrodes during processing. Thus, when RF power is provided by RF biased power supply 210 to chuck 206 and a suitable etching source gas is provided to the chamber of plasma wafer edge cleaning system 200, a plasma is struck and sustained in plasma region 240 to clean wafer edge area 214. In an embodiment, the frequency of the RF signal provided by the RF biased power supply is 13.56 Megahertz, for example.

In the configuration of FIG. 2, a plasma shield 250 formed of a suitable dielectric material such as quartz or aluminum oxide (Al₂O₃) is provided and disposed above the horizontal surface of substrate 204. In an embodiment, the plasma shield 250 may be formed of any suitable dielectric material that is compatible with the plasma wafer edge clean system. Furthermore, plasma shield 250 forms a limited gap between its lower surface 252 and the upper surface of substrate 204. Preferably this limited gap shown by reference number 260 is dimensioned to be less than the sheath thickness of the plasma to be formed in plasma region 240. In an embodiment, gap 260 may be less than about 1 mm, for example. Since the sheath thickness can be calculated for any given plasma, the thickness of gap 260 can vary depending on the specifics of a given plasma wafer edge cleaning system.

Furthermore, plasma shield 250 is extended beyond an edge 262 of substrate 204. In other words, the outer edge 264 of plasma shield 250 extends beyond outer edge 262 of substrate 204 by a given distance denoted by X in FIG. 2. This overextension dimension, X, is sufficiently dimensioned such that plasma is not present in the region of substrate 204 where there may be exposed metallization edge or residue. For example, if there exists metallization edge in region 270 of substrate 204, outer edge 264 of plasma shield preferably extends beyond outer edge 262 of substrate 204 by a sufficient overextension dimension X such that plasma is not present over region 270 of substrate 204 during plasma wafer edge cleaning. In an embodiment, overextension dimension X is about 0.5 mm. Although this overextension dimension X may vary depending on the specific plasma wafer edge cleaning to be performed. Nevertheless, overextension dimension X is at least zero in accordance with embodiments of the invention. Thus, the overextension of the dielectric plasma shield masks the metallization area of the wafer such that plasma cannot be formed in the area being masked by the physical plasma shield.

In an embodiment, to clean the back side of substrate 204, grounded plate 232, which is disposed below substrate 204, may be offset from grounded plate 230 which is disposed above substrate 204. As such, the plasma that is formed is asymmetrical with respect to wafer edge area 214 and a greater area on the back side of substrate 204 may be cleaned relative to the top side of substrate 204. To further clarify, the lower grounded plate 232 extends further toward the center of substrate 204 such that at least a portion of the lower surface periphery of the substrate overlaps with the lower grounded plate 232.

In an embodiment, it is desirable to clean an area in the wafer edge that is 2 mm from the outer edge 262 of substrate 204 when measured along the top side of the substrate and 5 mm from the outer edge 262 of substrate 204 when measured along the back side of the substrate.

As mentioned, it has been found that the use of a non-carbon-containing fluorinated chemistry substantially reduces or eliminates arcing events in the plasma wafer edge cleaning chamber. Thus, alternatively or additionally, a non-carbon-containing fluorinated plasma etching source gas may be provided to plasma wafer edge cleaning system 200 in order to further reduce or eliminate arcing events during plasma wafer edge cleaning. Alternatively or additionally, the plasma etching source gas employed to generate a plasma in plasma region 240 of plasma wafer edge cleaning system 200 may include helium and/or hydrogen to further reduce or substantially eliminate arcing events.

Alternatively or additionally, the automated process control computer that controls plasma wafer edge cleaning system 200 may be programmed to ramp up the power provided by RF biased power supply 210 to chuck 206 such that RF power is provided in a gradual manner to strike and sustain a plasma in plasma region 240. It is believed that gradually increasing the RF power to plasma wafer edge cleaning system 200 reduces the sudden change in the impedance and/or plasma potential, thereby substantially reducing or eliminating arcing events in plasma wafer edge cleaning system 200. Note that it is also possible to employ non-carbon-containing fluorinated etching source gas and/or helium/hydrogen in the etching source gas and/or software-controlled gradual RF power ramp up in a plasma wafer edge cleaning system that does not provide an overextending plasma shield over the substrate 204. In other words, each of the four techniques discussed herein (overextending the plasma shield over the substrate, using non-carbon-containing fluorinated plasma etching source gas, adding helium and/or hydrogen to the plasma etching source gas, software-controlled gradual RF power ramp up) may be performed in any combination with one another.

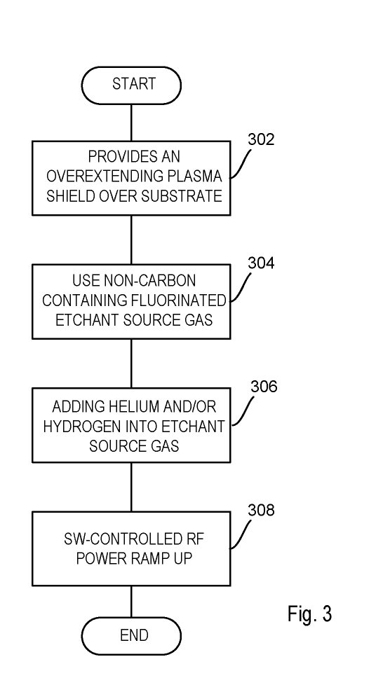

FIG. 3 shows, in accordance with an embodiment of the invention, various techniques that may be employed to substantially reduce or eliminate arcing events during a plasma wafer edge cleaning process in a plasma wafer edge cleaning system. The steps of FIG. 3 are intended to be performed either additionally or in the alternative in any suitable combination. The steps of FIG. 3 may be performed in any order, in an embodiment.

In step 302, an overextending plasma shield is provided over the substrate such that the plasma formed to perform the plasma wafer edge cleaning is not present over the exposed metallization area. In this step, the gap between the lower edge of the physical plasma shield and the upper surface of the substrate as well as the overextension dimension are configured such that arcing from the plasma sheath to the exposed metallization area and/or the device-forming area of the substrate is substantially reduced or eliminated.

In step 304 the etching source gas represents a non-carbon-containing fluorinated etching source gas. For example, for polymer removal in the wafer edge area, plasma etching source gas such as SF₆ and/or NF₃ may be employed. In step 306 helium and/or hydrogen may be added to the etching source gas. In an embodiment, the helium is preferably at least 10% of the total etching source gas flow. Hydrogen may be present in any percentage of the total etching gas flow, in an embodiment.

In step 308 the RF power provided to strike and/or sustain the plasma employed for the plasma wafer edge cleaning is ramped up gradually using a software-controlled process. As mentioned, this software control may be integrated into the automated process control computer that is employed to control the plasma wafer edge clean system.

In an example of a plasma wafer edge cleaning process, a 300 mm wafer is processed in a capacitively-coupled plasma wafer edge cleaning system. 20 sccm (Standard Cubic Centimeter per Minute) of CF₄ and 200 sccm of CO₂ are employed as the main wafer edge etching source gas.

In this example, since the plasma wafer edge cleaning system employs an overextending plasma shield, even a carbon-containing etching source gas may be employed without risking arc-related damage to these devices on the substrate. This example illustrates that the use of non-carbon-containing fluorinated etching source gas may be performed as either additionally or alternatively to the use of an overextending plasma shield.

In the example of plasma wafer edge cleaning, the pressure in the plasma wafer edge clean chamber is maintained at about 1.5 Torr, and RF biased power is about 700 Watts with the RF frequency being about 13.56 Megahertz. About 100 sccm of helium/hydrogen mixture is also added to the etching source gas (with hydrogen being 4% of the helium/hydrogen mixture by flow). It has been found that arc-related damage is absent in the example edge when the overextending shield is disposed about 1 mm from the substrate surface and the overextension dimension beyond the substrate outer edge is about 0.5 mm.

As can be appreciated from the foregoing, embodiments of the invention provide one or more tools or control knobs to enable a manufacturer to address the arc-related damage problem during plasma wafer edge cleaning. By using one or more of the techniques discussed herein, the semiconductor device manufacturer can effectively perform plasma-enhanced wafer edge cleaning without risking damage to the devices on the substrate even when there exists exposed metallization in between plasma processing steps.

While this invention has been described in terms of several preferred embodiments, there are alterations, permutations, and equivalents, which fall within the scope of this invention. Also, the title, summary, and abstract are provided herein for convenience and should not be used to construe the scope of the claims herein. It should also be noted that there are many alternative ways of implementing the methods and apparatuses of the present invention. Although various examples are provided herein, it is intended that these examples be illustrative and not limiting with respect to the invention. It is therefore intended that the following appended claims be interpreted as including all such alterations, permutations, and equivalents as fall within the true spirit and scope of the present invention.

What is claimed is:

1. A plasma processing system having a plasma processing chamber configured for processing a substrate, comprising:
a RF power source;
a lower electrode configured to support said substrate during said processing, said lower electrode receiving at least an RF signal from said RF power source for generating a plasma within said plasma processing chamber during said processing;
a first annular grounded electrode disposed above said substrate;
a second annular grounded electrode disposed below said substrate, said first annular grounded electrode and said second annular grounded electrode being disposed such that a circumferential edge of said substrate is exposed in a direct line-of-sight manner to at least a portion of said first annular grounded electrode and at least a portion of said second annular grounded electrode; and
a plasma shield disposed above at least a portion of said substrate, said plasma shield being configured to prevent said plasma from being formed in a region between said plasma shield and said portion of said substrate during said processing.

2. The plasma processing system of claim 1 wherein said second annular grounded electrode extends further toward a center of said substrate relative to said first annular grounded electrode such that at least a portion of a lower surface periphery of said substrate overlaps said second annular grounded electrode.

3. The plasma processing system of claim 1 further comprising means for gradually ramping up a RF bias power supplied to said lower electrode.

4. The plasma processing system of claim 1 wherein said plasma shield is configured to be separated from an upper surface of said substrate by a gap that is less than a sheath thickness of said plasma during said processing.

5. The plasma processing system of claim 1 wherein said plasma shield represents a circular structure that extends beyond a periphery of said substrate during said processing.

6. The plasma processing system of claim 5 wherein said plasma shield extends beyond said periphery by an overextension dimension, said overextension dimension being selected to prevent exposed metallization on a surface of said substrate from being exposed to said plasma.

7. The plasma processing system of claim 1 wherein said RF signal has a frequency of 13.56 MHz.

8. A method for processing a substrate in a plasma processing chamber, said substrate being disposed on a lower electrode that forms a chuck during said processing, comprising:
providing a first annular grounded electrode disposed above said substrate;
providing a second annular grounded electrode disposed below said substrate, said first annular grounded electrode and said second annular grounded electrode being disposed such that a circumferential edge of said substrate is exposed in a direct line-of-sight manner to at least a portion of said first annular grounded electrode and at least a portion of said second annular grounded electrode;
providing a plasma shield disposed above at least a portion of said substrate, said plasma shield being configured to prevent said plasma from being formed in a region between said plasma shield and said portion of said substrate during said processing; and
generating a plasma in between said first annular grounded electrode and said second annular grounded electrode, thereby processing at least a portion of said circumferential edge of said substrate with said plasma.

9. The method of claim 8 wherein said second annular grounded electrode extends further toward a center of said substrate relative to said first annular grounded electrode such that at least a portion of a lower surface periphery of said substrate overlaps said second annular grounded electrode.

10. The method of claim 8 further comprising gradually ramping up a RF bias power supplied to said lower electrode while performing said generating said plasma.

11. The method of claim 8 wherein said plasma shield is configured to be separated from an upper surface of said substrate by a gap that is less than a sheath thickness of said plasma during said processing.

12. The method of claim 8 wherein said plasma shield represents a circular structure that extends beyond a periphery of said substrate during said processing.

13. The method of claim 12 wherein said plasma shield extends beyond said periphery by an overextension dimension, said overextension dimension being selected to prevent exposed metallization on a surface of said substrate from being exposed to said plasma.

14. The method of claim 8 wherein said RF signal has a frequency of 13.56 MHz.

15. The method of claim 8 wherein said plasma is formed from a process gas that does not employ carbon.

16. The method of claim 15 wherein said process gas is also a fluorinated gas.

17. The method of claim 8 wherein said plasma is formed of a process gas that includes at least one of hydrogen and helium.

18. A plasma processing system having a plasma processing chamber configured for processing a substrate, comprising:
a RF power source;
a lower electrode configured to support said substrate during said processing, said lower electrode receiving at least an RF signal from said RF power source for generating a plasma within said plasma processing chamber during said processing;
a substrate edge plasma generating arrangement including at least a first annular grounded electrode and a second annular grounded electrode, said first annular grounded electrode disposed above said substrate, wherein said first annular grounded electrode does not overlap said substrate, said second annular grounded electrode disposed below said substrate, said first annular grounded electrode and said second annular grounded electrode being disposed such that a circumferential edge of said substrate is exposed in a direct line-of-sight manner to at least a portion of said first annular grounded electrode and at least a portion of said second annular grounded electrode; and
plasma shielding means disposed above at least a portion of said substrate, said plasma shielding means being configured to prevent said plasma from being formed near an exposed metallization region on said substrate so as to cause arcing to said exposed metallization region during said processing.

19. The plasma processing system of claim 18 wherein said second annular grounded electrode extends further toward a center of said substrate relative to said first annular grounded electrode such that at least a portion of a lower surface periphery of said substrate overlaps said second annular grounded electrode.

20. The plasma processing system of claim 18 further comprising means for gradually ramping up a RF bias power supplied to said lower electrode.

21. The plasma processing system of claim 18 wherein said plasma shielding means is configured to be separated from an upper surface of said substrate by a gap that is less than a sheath thickness of said plasma during said processing.

22. The plasma processing system of claim 18 wherein said plasma shielding means represents a circular structure that extends beyond a periphery of said substrate during said processing.

23. The plasma processing system of claim 18 wherein said RF signal has a frequency of 13.56 MHz.
